(19) United States
(12) Patent Application Publication
(10) Pub. No.: US 2005/0102823 A1
(43) Pub. Date: May 19, 2005

(54) Method of producing fuses

(75) Inventor: Chang-Il Kim, Anyang-city (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: AL:PI CO., LTD, Dongan-gu, Anyang-city (KR)

(21) Appl. No.: 10/505,365

(22) PCT Filed: Mar. 14, 2003
(86) PCT No.: PCT/KR03/00503

(30) Foreign Application Priority Data
Mar. 15, 2002 (KR) 10-2002-0014230

(51) Int. Cl. H01H 69/02; H01R 43/00; H05K 7/00

(52) U.S. Cl. 29/623; 29/874; 29/848; 29/827; 361/837

(57) ABSTRACT

A method is provided for producing fuses with an increased yield rate and in a highly automated fashion. The method comprises the steps of processing a metal sheet into a blank having a plurality of continuously distributed pairs of lead conductors, molding an insulator base integrally with each pair of the lead conductors, electrically interconnecting the lead conductors of the respective conductor pair with a fusible connector, and severing the lead conductors from the blank. Additionally, a protection cap is coupled to the insulator base in such a manner that the cap can enclose the fusible connector in its entirety.

### TECHNICAL FIELD

The present invention relates to a method for producing fuses, and more particularly to a method for producing quality fuses with an increased yield and in a highly automated fashion.

### BACKGROUND ART

As well known to those skilled in the art, a fuse has a fusible metal connector, which is melted by an excessive electric current, and thus is broken. When electric current having more than a prescribed value flows, the fusible metal connector is broken to automatically shut off the electric current so that electronic parts and electric circuits are protected. Such a fuse has been developed in various structures and forms. Recently, a micro fuse applicable to a small-sized electronic product has been developed.

A conventional micro fuse (hereinafter, referred simply to as “fuse”) is shown, in cross section, in FIG. 1. As shown in FIG. 1, the fuse 1 includes an insulator base 3. The insulator base 3 is made up of a disc-shaped member with a prescribed thickness. The insulator base 3 has a pair of through-holes 3a, each of which penetrates from the top surface of the insulator base 3 to the bottom surface of the insulator base 3. The through-holes 3a are spaced apart from each other.

The fuse 1 further includes a pair of lead wires 5, which are fixedly fitted in the through-holes 3a of the insulator base 3, respectively, and a fusible metal connector 7 for electrically connecting the upper ends of the lead wires 5. Preferably, the fusible metal connector 7 is securely attached to the lead wires 5, for example, by means of soldering. The fusible metal connector 7 is melted and thus automatically broken to shut off electric current going through the lead wires when the electric current has more than a prescribed value.

Preferably, the fuse 1 may further include a cap 9 for enclosing the fusible metal connector 7 as the case may be, as shown in FIG. 1. The cap 9 protects the fusible metal connector 7 from foreign substances and external shocks. The cap 9, which is fitted on the insulator base 3, is prevented from coming off the insulator base 3 by engagement means. The engagement means comprises at least one protrusion 3b formed on the outer circumference of the insulator base 3, and at least one annular groove 9a formed on the inner circumference of the cap 9. The protrusion 3b is engaged with the annular groove 9a. More specifically, after the cap 9 has been fitted on the insulator base 3, the cap 9 is securely joined with the insulator base 3, and thus the cap 9 is prevented from accidentally coming off the insulator base 3 by engagement of the protrusion 3b with the annular groove 9a.

The fuse constructed as described above may be produced by various ways. For example, a method for producing fuses has been proposed which comprises the steps of: injection molding a insulator base having a through-hole; unwinding a rolled lead wire having a circular section to cut it into a prescribed length; and securely inserting the cut lead wire into the through-hole of the insulator base.

However, the aforesaid conventional method for producing fuses has problems in that a great deal of manual work is required during production of the fuses, thus resulting in a reduced productivity and an increased number of defective fuses. More specifically, most of the production process, including the steps of injection molding a insulator base having a through-hole, unwinding a rolled lead wire having a circular section to cut it into a prescribed length, and securely inserting the cut lead wire into the through-hole of the insulator base, are performed by manual labor. Consequently, it becomes difficult and troublesome to produce the fuses. Furthermore, it takes a lot of time to produce the fuses, which leads to decreased productivity. Besides, the lead wire tends to be easily bent when it is forcibly inserted into the through-hole of the insulator base, and there is a tendency that the lead wire may be unwantedly separated from the through-hole while the fuse is produced or used.

Another method for producing fuses has been also proposed which comprises the steps of: unwinding a rolled lead wire having a circular section to cut it into a prescribed length; arranging the cut lead wires in an injection mold in a spaced-apart relationship with each another; and injecting molten resin into the injection mold.

However, the aforesaid conventional method for producing fuses also has problems in that a great deal of manual work is required in the course of unwinding a rolled lead wire having a circular section, cutting the unwound lead wire to a prescribed length, arranging the cut lead wires in an injection mold, and injecting a resin into the injection mold. Furthermore, the fuse has to be produced one at a time, which leads to a prolonged production time and a decreased productivity.

In addition, according to the conventional method, a rolled elongated metal wire is used, which tends to go back to its original shape in the course of molding. This makes it dificult to affix the lead wire at the desired position. Especially, the lead wire has a tendency to return to its original rolled form even after it is fixed to the insulator base, which may result in production of defective fuses.

### DISCLOSURE OF THE INVENTION

Therefore, the present invention has been made in view of the problems inherent in the prior art method, and it is an object of the present invention to provide a method for producing quality fuses in a large quantity and in a highly automated fashion.

It is another object of the present invention to provide a method for producing fuses which is capable of preventing a flexural deformation of lead wires during the production of the fuses, thus minimizing generation of bad quality fuses.

In accordance with the present invention, there is provided a method for producing fuses comprising the steps of: processing a metal sheet into a blank having a plurality of continuously distributed pairs of lead conductors; molding an insulator base integrally with each pair of the lead conductors; electrically interconnecting the lead conductors of the respective conductor pair with a fusible connector; and severing the lead conductors from the blank.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side view, in cross section, showing one example of conventional fuses;

FIGS. 2A to 2H show various steps employed in a method for producing fuses according to a preferred embodiment of the present invention, respectively;

FIGS. 3A to 3E are plan views illustrating configuration of metal sheets at the repective step of the inventive method;

FIG. 3F is a side view showing the step of fitting a protective cap on an insulator base to enclose a fusible metal connector;

FIG. 4 shows a method for producing fuses according to another preferred embodiment of the present invention;

FIG. 5 is a plan view of a metal sheet segment obtained by the method of FIG. 4;

FIG. 6 is a plan view of another example of a metal sheet obtained in a blanking process according to the present invention; and

FIG. 7 is a plan view of the metal sheet shown in FIG. 6 and the insulator base integrally formed therewith.

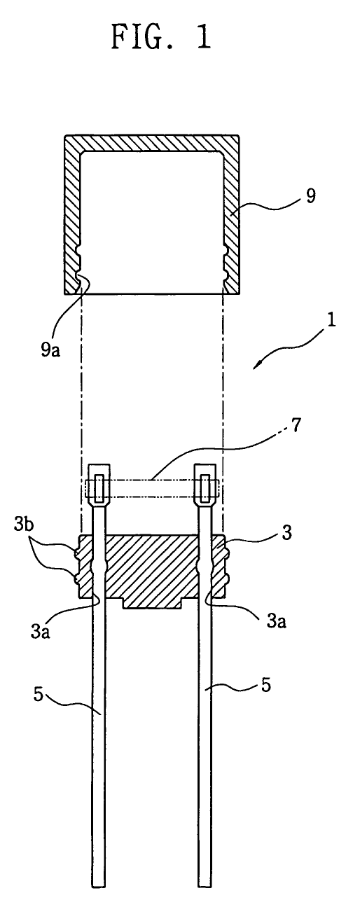

### BEST MODE FOR CARRYING OUT THE INVENTION

A preferred method for producing fuses according to the present invention will now be described with reference to the accompanying drawings. In the present specification, the term “blank” denotes a half-finished product obtained by pressing a metal sheet into a plurality of pairs of lead conductors.

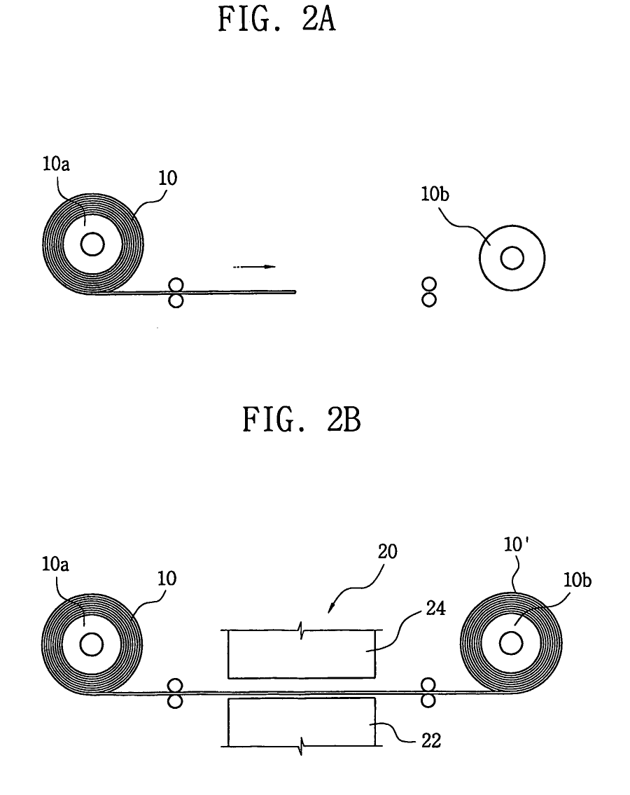

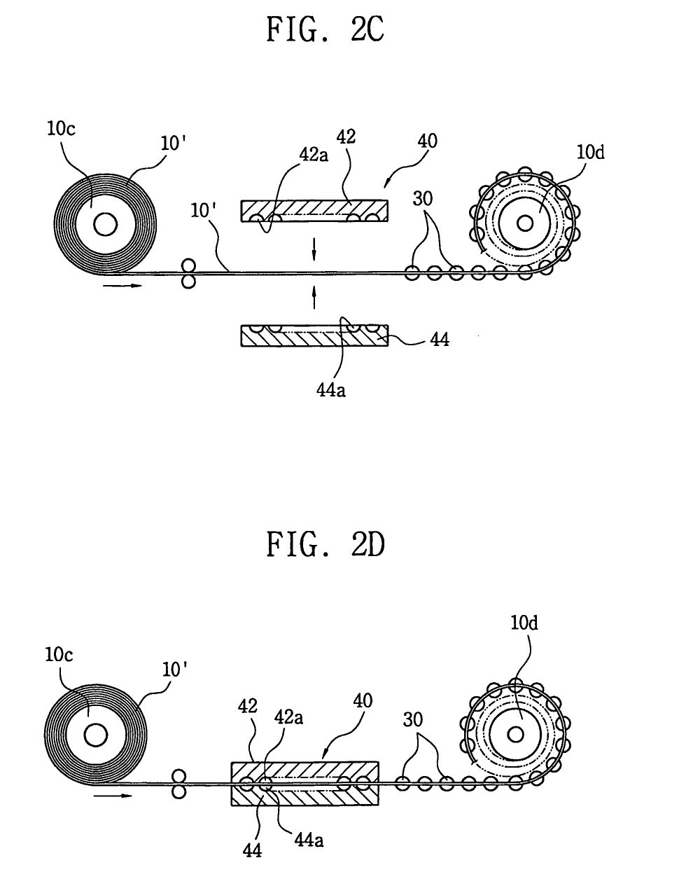

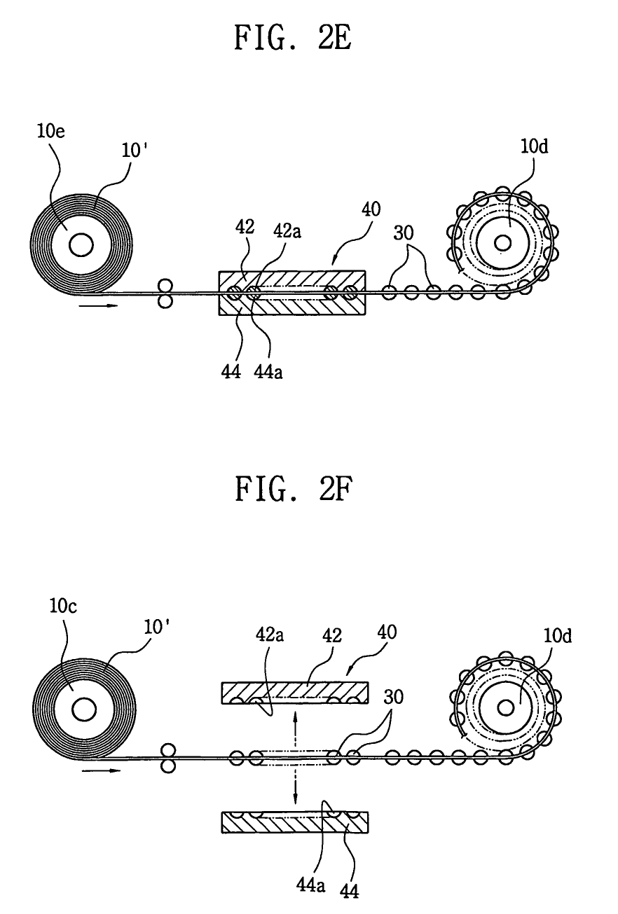

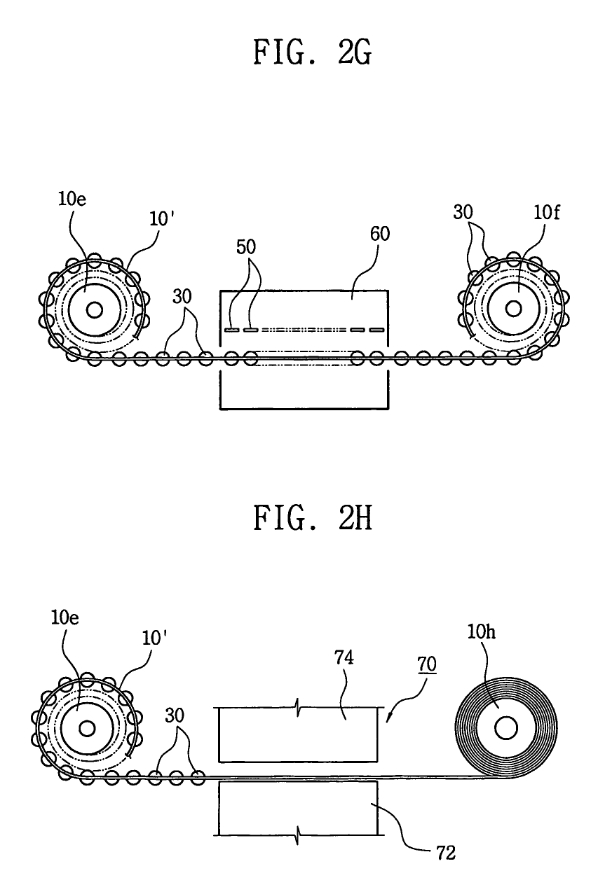

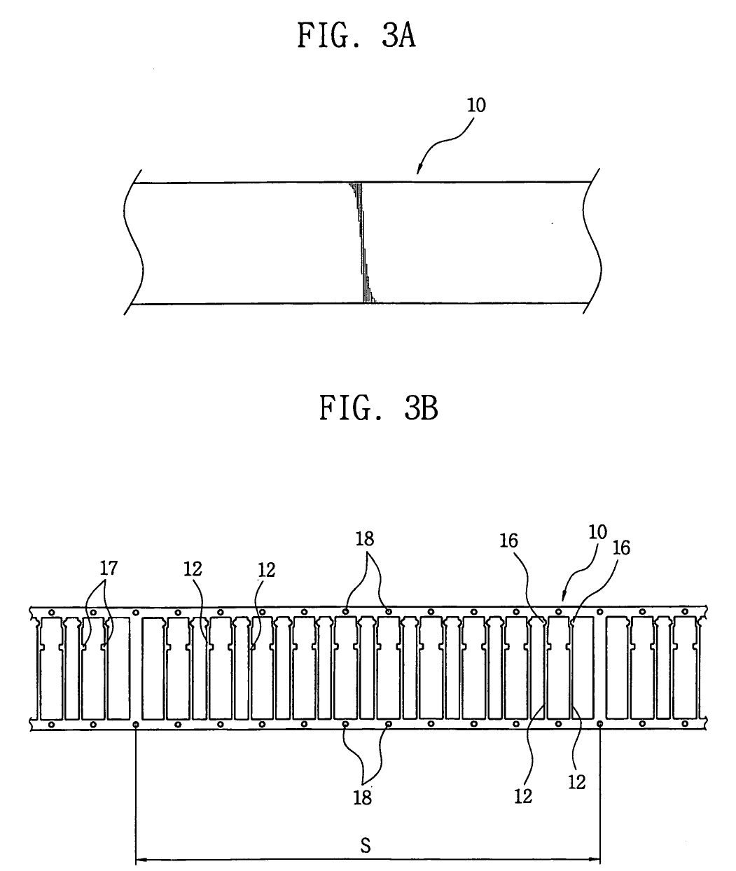

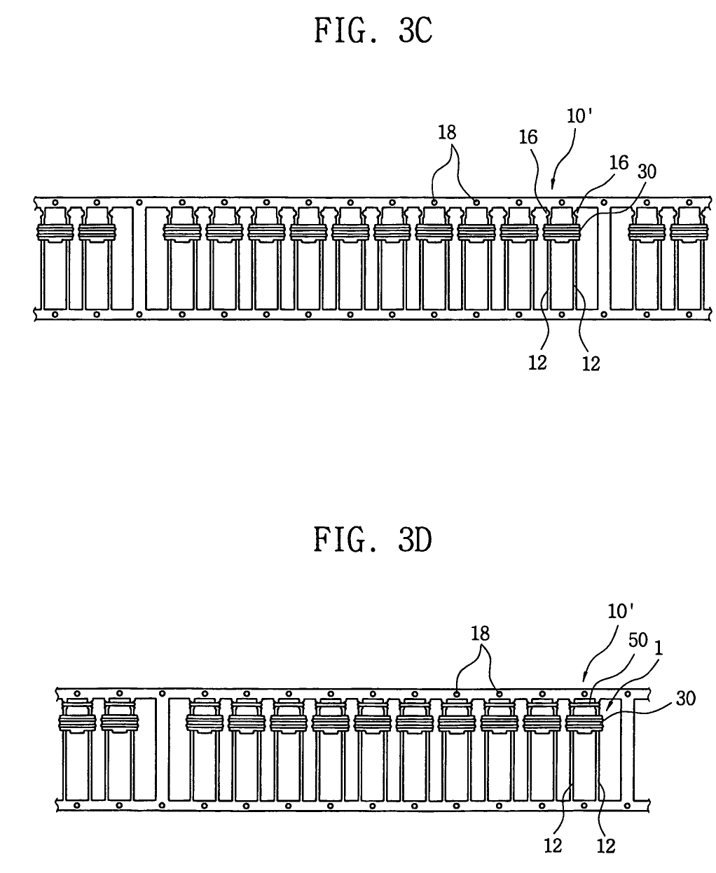

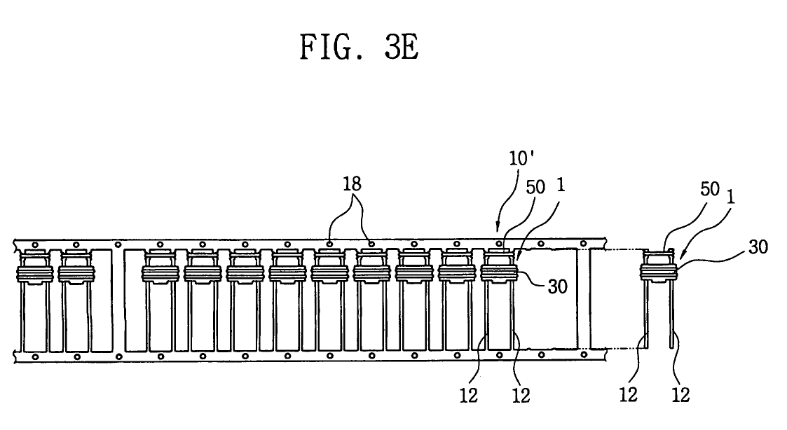

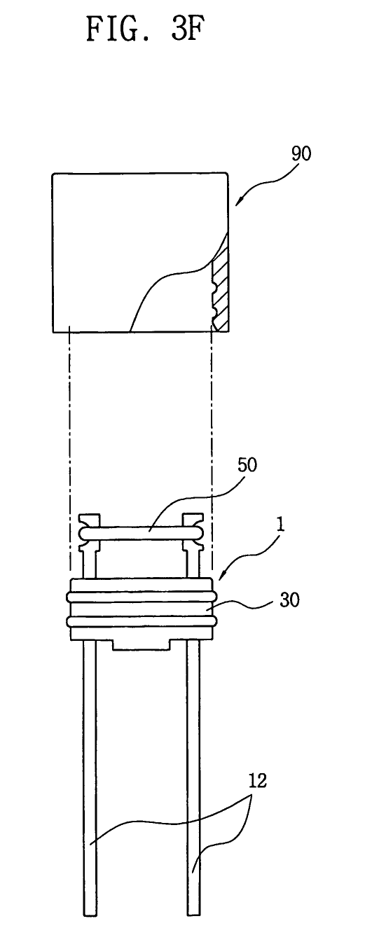

FIGS. 2A to 2H show a series of steps employed in the method for producing fuses according to a preferred embodiment of the present invention, and FIGS. 3A to 3E show configuration of metal sheets formed at the respective step of the inventive method.

The fuse production method according to the present invention makes use of a metal sheet 10, which may be a rolled continuous strip as shown in FIG. 2A. The metal sheet 10 is intermittently unwound from a supply reel 10a and transferred to a take-up reel 10b. One example of the metal sheet 10 may be a copper sheet. The width and length of the metal sheet 10 are appropriately determined depending upon the size of a fuse to be produced.

According to the present invention, the metal sheet 10, which is intermittently unwound from the supply reel 10a and transferred to the take-up reel 10b, is blanked by means of a press die 20, as shown in FIG. 2B. At this step, the metal sheet 10 is stamped so that a plurality of continuously distributed pairs of lead conductors 12 are formed on the metal sheet 10, as shown in FIG. 3B. Hereinafter, the metal sheet having the lead conductors 12 formed thereon will be referred to as a “blank”, which is indicated by reference numeral 10′ in the drawings, so that it is clearly distinguished from the original metal sheet 10 with no lead conductors 12.

At the blanking step, the bottom surface of the metal sheet 10 is supported by a lower die part 22 of the press die 20, and then the metal sheet 10 is pressed by means of a upper punch part 24 of the press die 20, as shown in FIG. 2B, so that a blank 10′ having continuously distributed pairs of the lead conductors 12 is obtained.

At the blanking step, a connector receiving depressed portion 16 is formed at one end part of each of the lead conductors 12 of the respective conductor pair, and a mutually confronting protruded lug portion 17 is also formed at the intermediate part of each of the lead conductors 12 of the respective conductor pair, as shown in FIG. 3B. Preferably, the connector receiving depressed portion 16 is formed at the outer side of each of the lead conductors 12 of the respective conductor pair, and the protruded lug portion 17 is formed at the inner side of each of the lead conductors 12 of the respective conductor pair but below the connector receiving depressed portion 16. In addition, a plurality of spaced-apart guide holes 18 are formed at the opposite lateral edges of the blank 10′, as shown in FIG. 3B. The connector receiving depressed portions 16 are provided for securely receiving a fusible metal connector 50, which will be described later, and the protruded lug portions 17 are provided for preventing the lead conductors 12 from coming off an insulator base, which will be also described later, when the fuse is used. Into the guide holes 18 are inserted pilot pins of an injection mold 40 or sprocket pins of a conveyor (not shown) at a molding step, which will be set forth later.

It is preferable to form as many lead conductors 12 as possible by one pressing work at the blanking step. For example, it is desirable to form ten pairs of lead conductors 12 every time the metal sheet 10 is transferred by one step S, considering the size of the injection mold 40. Nevertheless, it is also possible to form less than or more than ten pairs of lead conductors 12 by one pressing work. It should be noted, therefore, that the present invention is not limited to the specific number of the lead conductor pairs.

Referring to FIGS. 2C to 2F, the method for producing fuses further comprises the step of molding an insulator base 30 integrally with each pair of the lead conductors 12 formed on the blank 10′ each time the blank 10′ formed at the blanking step is intermittently unwound from the supply reel 10c and transferred to the take-up reel 10d.

At the molding step, an injection mold 40 having a plurality of cavities 42a and 44a corresponding to each pair of the lead conductors 12 is prepared as shown in FIG. 2C. The blank 10 is disposed between an upper mold part 42 and a lower mold part 44 of the injection mold 40. Subsequently, the upper mold part 42 of the injection mold 40 is put on the lower mold part 44 of the injection mold 40 to close each of the cavities 42a and 44a, as shown in FIG. 2D. Into the closed cavities 42a and 44a of the upper mold part 42 and the lower mold part 44 of the injection mold 40 is poured a flowable molding material, such as synthetic resin 32, as shown in FIG. 2E. After a prescribed time passes, the upper mold part 42 of the injection mold 40 is separated from the lower mold part 44 of the injection mold 40, as shown in FIG. 2F, so that the blank 10′ having the insulator base 30 integrally molded with each pair of the lead conductors 12 is obtained as shown in FIG. 3C.

The insulator base 30 is integrally molded with each pair of the lead conductors 12 of the blank 10′ by means of the aforesaid injection molding step. Consequently, each pair of the lead conductors 12 are uniformly spaced apart from each other by means of the insulator base 30 after the fuse is finally produced.

Referring to FIG. 2G, the lead conductors 12 of the respective conductor pair of the blank 10′ are interconnected by means of the fusible metal connector 50 while the blank 10′ having passed through the injection molding step is intermittently unwound from a supply reel 10e and transferred to a take-up reel 10f.

More specifically, between the supply reel 10e and the take-up reel 10f is provided a soldering device 60. A fusible metal connector 50 is attached to each of the lead conductors 12 at one end of each of the lead conductors 12 of the respective conductor pair by virtue of the soldering device 60. At this step, the lead conductors 12 of the respective conductor pair are electrically interconnected via the fusible metal connector 50, assuring that electric current flows from one of the lead conductors 12 to the other when the fuse is used. The construction and the operation of the soldering device 60 is well known to those skilled in the art, the detailed description of which will accordingly not be given. An ultrasonic bonding device or a spot welding device may be used instead of the soldering device, if necessary.

The method for producing fuses further comprises the step of severing the lead conductors 12 from the blank 10′ while the blank 10′ having passed through the soldering step is intermittently unwound from a supply reel 10g and transferred to a take-up reel 10h, as shown in FIG. 2H.

At this step, the lead conductors 12 are severed from the blank 10′. To this end, a cutting device 70 having a lower die part 72 and an upper punch part 74 is prepared. The bottom surface of the blank 10′ is supported by the lower die part 72 of the cutting device 70, and the lead conductors 12 of the blank 10′ are severed by means of the upper punch part 74 of the cutting device 70. In this way, the lead conductors 12 are separated from the blank 10′ with the result that the complete fuse 1 having the insulator base 30, a pair of the lead conductors 12, and the fusible metal connector 50 is finally produced as shown in FIG. 3E.

As shown in FIG. 3F, on the insulator base 30 of the fuse 1 obtained from the aforesaid steps is fitted a protective cap 90 for enclosing the fusible metal connector 50. The protective cap 90 prevents the fusible metal connector 50 from being damaged due to external force which may exert in the course of packing, transportation, and use of the fuse.

In foregoing embodiment of the present invention, the method for producing fuses is adapted to independently perform the blanking, molding, soldering, and severing steps by use of the press, the injection mold, the soldering device, and the cutting device, all of which are individually provided. However, it is also possible to successively perform all the steps by using a full or partial in-line arrangement of the press, the injection mold, the soldering device, and the cutting device provided between the supply reel 10a and the take-up reel 10b.

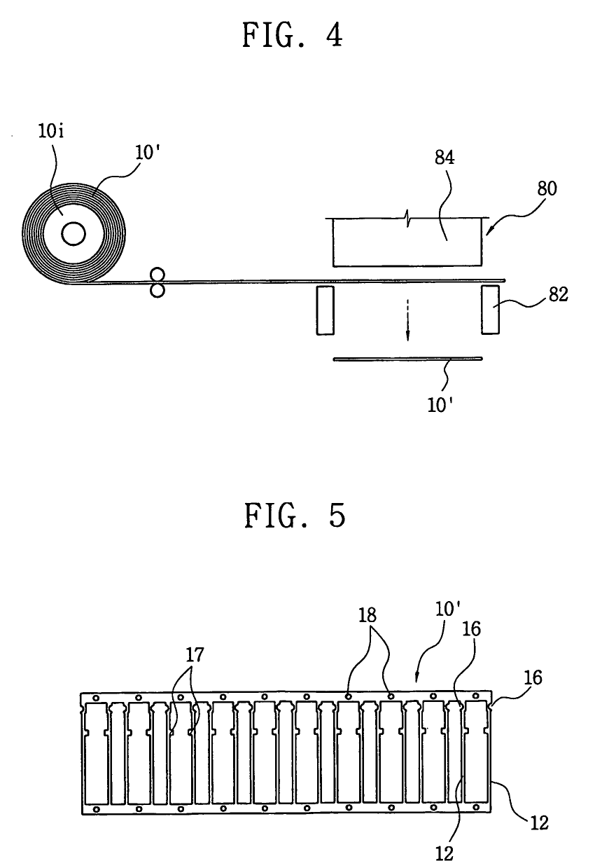

A method for producing fuses according to another preferred embodiment of the present invention is shown in FIG. 4. The method according to this embodiment further comprises the step of cutting the blank 10′ formed at the blanking step (Refer to FIG. 2B) to a prescribed length to obtain a blank segment 10″ as the blank 10′ is unwound from a supply reel 10i and transferred to the subsequent step.

As shown in FIG. 4, a cutting device 80 having a lower die part 82 and an upper punch part 84 is prepared. The bottom surface of the blank 10′ is supported by the lower die part 82 of the cutting device 80, and the top surface of the blank 10′ is pressed by means of the upper punch part 84 of the cutting device 80, so that the blank 10′ can be cut to consequently obtain the blank segment 10″. This blank segment 10″ has an advantage in that its storing and handling are easy and convenient. The blank segment 10″ obtained at the cutting step successively passes through the subsequent steps, such as the molding, soldering, and severing steps, which are similar to the steps of the method according to the first embodiment of the present invention, to thus obtain the finished fuse 1.

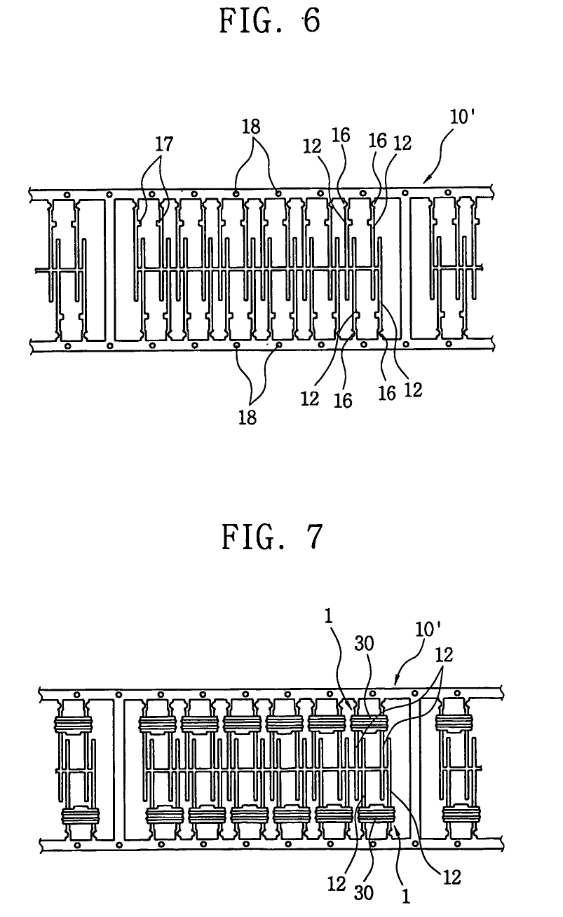

A modification of the blank 10′ which can be used in the method for producing fuses of the present invention is shown in FIG. 6. The blank 10′ has first pairs of lead conductors 12 arranged in one row and second pairs of lead conductors 12 arranged in the other row. The first and second pairs of lead conductors 12 are disposed at the right and left parts along the length of the blank 10′, respectively. The lead conductors 12 of the first and second conductor pairs are alternately arranged, as shown in FIG. 6.

The blank 10′ illustrated in FIG. 6 has an increased number of lead conductors per unit length. This help assure an improved production efficiency of the fuses and a decreased production cost.

### Industrial Applicability

As is apparent from the above description, the present invention enables quality fuses to be produced at an increased yield rate through the use of a metal sheet. The inventive method is particularly suitable for mass-production of standardized fuses mainly because a multiple number of fuses can be simultaneously produced per process cycle. Furthermore, it becomes possible to minimize unwanted flexural deformation of lead wires during the production of the fuses, thus suppressing creation of defective fuses.

Although the preferred embodiments of the present invention have been disclosed for illustrative purposes, those skilled in the art will appreciate that various modifications, additions and substitutions are possible, without departing from the scope and spirit of the invention as defined in the accompanying claims.

1. A method for producing fuses comprising the steps of:
processing a metal sheet into a blank having a plurality of continuously distributed pairs of lead conductors;
molding an insulator base integrally with each pair of the lead conductors;
electrically interconnecting the lead conductors of the respective conductor pair with a fusible connector; and
severing the lead conductors from the blank.

2. The method as set forth in claim 1, further comprising the step of fitting a protective cap on the insulator base to enclose the fusible connector.

3. The method as set forth in claim 1, wherein said metal sheet is a rolled continuous strip.

4. The method as set forth in claim 1, wherein said metal sheet is cut into a metal sheet segment of a prescribed length at said processing step.

5. The method as set forth in claim 1, wherein said pairs of lead conductors are arranged in a single row along the length of the metal sheet at said processing step.

6. The method as set forth in claim 1, wherein said pairs of lead conductors are arranged in two or more parallel rows at said processing step.

7. The method as set forth in claim 1, wherein a depressed portion for receiving the fusible connector is formed at one end portion of each of the lead conductors at said processing step.

8. A fuse produced by the method as set forth in claim 1.

9. A fuse produced by the method as set forth in claim 2.

10. A fuse produced by the method as set forth in claim 3.

11. A fuse produced by the method as set forth in claim 4.

12. A fuse produced by the method as set forth in claim 5.

13. A fuse produced by the method as set forth in claim 6.

14. A fuse produced by the method as set forth in claim 7.
